(19) United States
(12) Patent Application Publication
(10) Pub. No.: US 2009/0188559 A1
(43) Pub. Date: Jul. 30, 2009

(54) ULTRAVIOLET CURED COATING SYSTEM

(76) Inventor: Jeffrey E. Nesbitt, Lititz, PA (US)

Correspondence Address: KENYON & KENYON LLP, ONE BROADWAY, NEW YORK, NY, 10004, US

(21) Appl. No.: 12/362,549

(22) Filed: Jan. 30, 2009

Related U.S. Application Data
(60) Provisional application No. 61/063,092, filed on Jan. 30, 2008.

(51) Int. Cl. H01L 31/042; C08F 2/46; C08K 3/22; C08K 5/3472; C08K 5/3492

(52) U.S. Cl. 136/256; 522/173; 522/81; 522/64; 522/75; 977/773

(57) ABSTRACT

The present invention is directed to ultraviolet cured coating compositions. More specifically, the present invention is directed to urethane/acrylic coating compositions that contain additives for the absorption of ultraviolet radiation and the reflection of infrared radiation and which are UV cured.

### FIELD OF THE INVENTION

The present invention is directed to ultraviolet cured coating compositions. More specifically, the present invention is directed to urethane/acrylic coating compositions that contain additives for the absorption of ultraviolet radiation and the reflection of infrared radiation and which are UV cured.

### BACKGROUND OF THE INVENTION

Products that are used in applications that are exposed to solar radiation often suffer from long-term weathering and degradation. For example, exterior building products are exposed to solar UV radiation and to cycles of heating and cooling upon exposure to the sun. Composite building materials, which use a reinforcing filler and/or fiber in a polymer matrix, often show poor long term weatherability. UV and/or heat sensitive polymer matrix materials such as vinyl, polyolefins, styrenics (including ABS, ASA), polycarbonates, polyesters and other material are susceptible to UV light and/or heat degradation over long periods of time.

Moreover, these products often suffer from loss of color and other degradation. Composite building materials often contain one of more pigments. These pigments are commonly susceptible to degradation upon exposure to solar UV and/or IR radiation. Many such products, although brightly colored upon installation, loose the coloration after only a few seasons of exposure. Additionally, in certain applications, such as decking, it is highly desirable that the material have a low solar gain so that it maintains a temperature that is comfortable to the touch when exposed to sunlight. Thus, methods for absorption of ultraviolet energy and reflection of infrared energy may be required to improve the long term usefulness of composite building materials, particularly for outdoors applications.

Photovoltaic devices, such as solar cells, are devices that convert light energy into electrical energy. Solar cells have many applications. Individual cells are used for powering small devices such as electronic calculators. Photovoltaic arrays generate a form of renewable electricity, particularly useful in situations where electrical power from the grid is unavailable such as in remote area power systems. Photovoltaic electricity is also increasingly employed in grid-tied electrical systems.

In the manufacture of many photovoltaic cells, a transparent encapsulant material is used to protect the solar cells from breakage and to help seal the cells into the overall module structure. The encapsulant material is usually a thermoplastic. The thermoplastic is melted, and then flows to fill in any open spaces in the module and bonds to all adjacent surfaces. The most widely used encapsulant material for solar cell modules is a co-polymer of vinyl acetate and ethylene, known as ethylene vinyl acetate (EVA). EVA is used to encapsulate and seal both thin film and crystalline silicon solar cell modules. Other polymeric materials are also used to encapsulate solar cells.

Historically, solar cells have suffered from degradation including a loss of power conversion efficiency over time upon exposure to solar UV radiation and to cycles of heating and cooling upon exposure to the sun. Also, organic solar cells made to date suffer from degradation upon exposure to UV light, and hence have lifetimes which are too short to be viable in outdoor applications. Dye-sensitized solar cells also suffer from degradation under heat and UV light.

It is therefore desirable to develop a means of protecting a variety of substrates from the adverse effects of long term exposure to ultraviolet radiation and to infrared radiation.

### SUMMARY OF THE INVENTION

The present invention provides a coating composition that provides protection from the adverse effects associated with long term exposure to ultraviolet radiation and to infrared radiation (heat) from the sun. The coating compositions of the present invention are urethane/acrylic coatings that comprise an ultraviolet protective agent and an infrared reflective agent. In preferred embodiments of the invention the coating composition comprises a photoinitiator and is cured by exposure to ultraviolet radiation. The ultraviolet curing of a coating that contains an ultra-violet protective agent and an infra-red reflective agent, and other optional components that may absorb or reflect ultraviolet radiation, presents a particular difficulty. Each of these components may interfere with the transmission of the frequencies of ultraviolet radiation that are needed by the photoinitiator to initiate curing of the coating. Interference with transmission of the frequencies of ultraviolet radiation used by the photoinitiator may result in incomplete curing and to a low adherence of the coating to the substrate.

The coatings of the present invention overcome this difficulty. In the coating compositions of the present invention, the infrared reflective agent and the ultra-violet protective agent are selected to provide an ultraviolet transmission window which is sufficiently transparent to frequencies of ultraviolet radiation that correspond to the frequency of ultraviolet radiation that is used by the photoinitiator.

Thus, the present invention provides a urethane/acrylic coating composition for coating onto a substrate that comprises (a) a urethane-acrylic precursor (monomer, oligomer, etc.); (b) an infrared reflective agent; (c) an ultraviolet protective agent; and (d) a photoinitiator. The infrared reflective agent and the ultraviolet protective agent are selected to provide an ultraviolet transmission window which is sufficiently transparent to select frequencies of ultraviolet radiation. The photoinitiator responds to UV light at a frequency within the ultraviolet transmission window.

The present invention also provides a composition comprising a substrate and a UV-cured coating applied on at least one surface of the substrate, wherein the coating has a pre-cure composition comprising a urethane-acrylic polymer precursor, an infrared reflective agent, an ultraviolet protective agent, and a photoinitiator. The infrared reflective agent and the ultraviolet protective agent are selected to provide an ultraviolet transmission window which sufficiently transmits ultraviolet radiation from an ultraviolet source with a frequency that corresponds to the photoinitiator. The photoinitiator is activated by ultraviolet light from the ultraviolet light source at a frequency within the ultraviolet transmission window.

In a preferred embodiment of the invention, the substrate to be coated with the urethane/acrylic coating is a composite building material, particularly for applications in which the composite building material is used outdoors. Thus, in preferred embodiments of the present invention, the method for producing the composite building material involves the step(s) of coating the substrate with a urethane/acrylic coating of the present invention, and curing the coating by exposure to ultraviolet radiation.

In another preferred embodiment of the invention, the substrate is a photovoltaic device. Thus, in preferred embodiments of the present invention, the method for producing the photovoltaic device involves the step(s) of coating the device with a urethane/acrylic coating of the present invention, and curing the coating by exposure to ultraviolet radiation.

An advantage of the product according to the present invention is that the final product is resistant to weathering. Particularly, the products according to the present invention are resistant to the long term degradation caused by exposure to ultraviolet radiation.

An additional advantage of the method and product according to the present invention is that the final product maintains a lower surface temperature when exposed to sunlight.

Other features and advantages of the present invention will be apparent from the following more detailed description of the preferred embodiment, taken in conjunction with the accompanying drawings which illustrate, by way of example, the principles of the invention.

### DESCRIPTION OF THE FIGURES

FIGS. 1A, 1B and 1C show schematic representations of the transmission of electromagnetic radiation for the ultraviolet absorption agent and the infrared reflective agent for embodiments of the invention.

FIGS. 2A and 2B show the emission spectra of UV-emitting bulbs for use in the coating curing process.

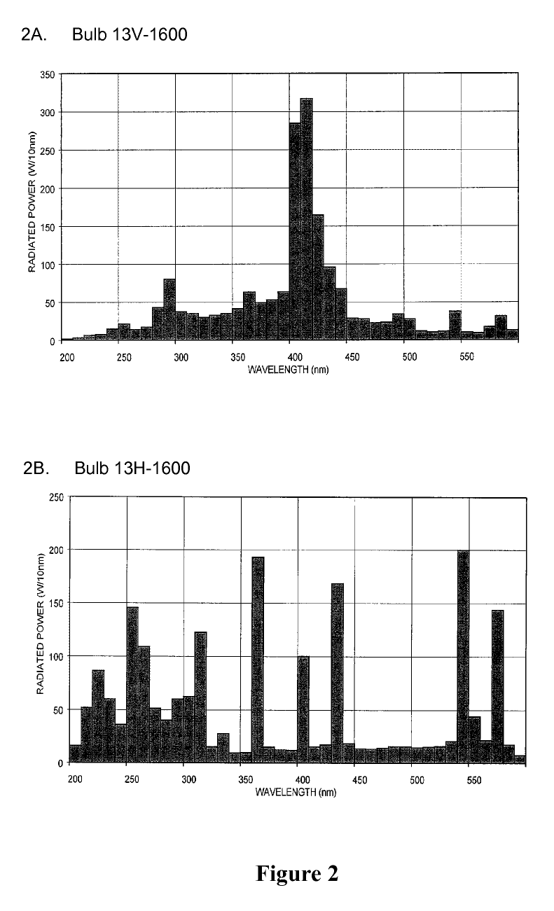

Wherever possible, the same reference numbers will be used throughout the drawings to refer to the same or like parts. Figures are not necessarily drawn to scale.

### DETAILED DESCRIPTION OF THE INVENTION

The coating composition of the present invention provides protection from the adverse effects associated with long term exposure to ultraviolet radiation and to infrared radiation (heat) from the sun. The degradation due to the exposure to solar radiation may be temperature dependent, i.e., it will occur more rapidly at higher temperatures. The general rule is that for every 10° C. increase in temperature the reaction rate will double. Tropical areas therefore suffer not only from increased UV exposure but also from faster reaction rates because of the increased temperatures. Thus, even substrates that primarily suffer from degradation due to exposure to ultraviolet radiation may benefit from the cooling effect of an infrared reflective additive to the coating.

The coating compositions of the present invention are urethane/acrylic coatings that comprise an ultraviolet absorption agent, an infra-red reflective agent and a photoinitiator. After application of the coating composition to a substrate, the coating is cured by exposure to ultraviolet radiation of a frequency that corresponds to the photoinitiator.

The present invention provides a process in which the urethane/acrylic coating composition is applied onto the substrate and cured using an ultraviolet radiation curing system. The UV curing of the coating is initiated by a photoinitiator that absorbs distinct energies of UV light. The preferred coatings also contain an IR reflective agent(s) and UV protective agent(s). The UV protective agents, IR-reflective agents, and other optional coating components may absorb or reflect frequencies of UV radiation. Thus, in the past, the use of such coating components in conjunction with UV curing systems would have been problematic, resulting in incomplete curing or low adhesion to the substrate. However, in the coating compositions of the present invention, these problems have been overcome by the selection of the IR-reflective agent, UV protective agent, photoinitiator and the UV light source which allow for an efficient curing of the UV cured urethane/acrylic coating. The coating components and the UV light source are selected in combination to allow for the sufficient transmission of a frequency of UV light from the emission source through the entire thickness of the coating to provide for effective UV-curing of the coating.

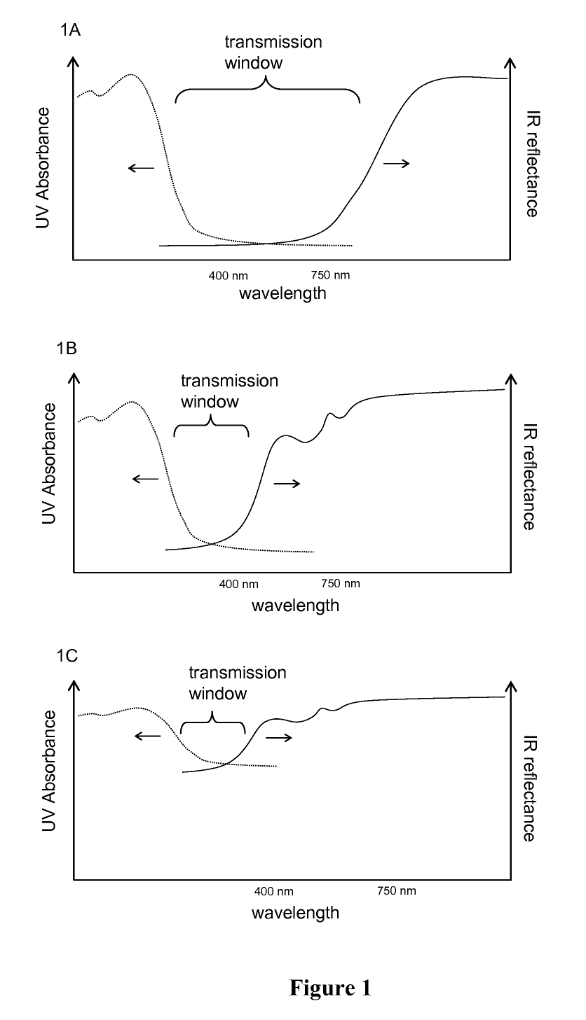

The preferred coating compositions of the present invention have a break (or “window”) in absorption/reflectance at wavelengths within the near UV spectrum, i.e., from about 380 to about 450 nm. This transmission window allows for the UV light within these wavelengths to sufficiently penetrate the coating and initiate the curing reaction. The transmission window may substantially transmit the UV light at that wavelength (FIGS. 1A and 1B), but more commonly will transmit only a portion of the UV light, (FIG. 1C). However, the window should allow for sufficient transmission of the UV light at that wavelength to allow efficient UV curing of the coating. Thus, in certain embodiments, the coating composition will transmit at least about 15% of the UV frequency that corresponds to the activation frequency of the photoinitiator. In other embodiments the coating composition will transmit at least about 20%, and more preferably at least about 30% of the UV frequency that corresponds to the activation frequency of the photoinitiator.

The exact position of this “window” may be adjusted with changes in the UV protection agent, IR-reflective agent and other additives that will influence the upper or lower bounds of the transmission window. In formulating the coatings that contain the urethane/acrylate precursor(s), IR reflective agent, UV protective agent, and other additives (gloss reducers, scratch and mar resistant additives) requires attention to the desired transmission window. To this end, use of spectrophotometric measurements of the entire coating system may be useful.

### Substrate

According to the present invention, the substrate is a material to which the coating will be applied that, when uncoated is susceptible to degradation over time upon exposure to ultraviolet radiation. Degradation as used herein includes any detriment in the properties of the substrate, including but not limited to chemical decomposition of a substrate component, fading or other changes in coloration, and changes in physical properties (strength, brittleness, etc.). The substrate may be comprised of any material, including but not limited to plastics, wood and metal. The substrate may incorporate a pigment or be a painted substrate.

In one embodiment, the substrate material is a composite building material (decking, siding, roofing, railing, and the like). Composite building materials comprise a reinforcing filler and/or fiber and a polymer matrix. Polymeric matrix materials may include, but are not limited to, poly(vinyl chloride) (PVC), chlorinated PVC, polyethylene, polypropylene, polystyrene, styreneacrylonitrile, acrylonitrile butadiene styrene, acrylic/styrene/acrylonitrile block terpolymer (ASA), polycarbonates, polyurethane, and co-polymers or combinations thereof. In preferred embodiments the polymeric matrix material is PVC resin. Many of the polymer matrix materials are susceptible to degradation upon long term exposure to ultraviolet radiation. Also, composite building materials often contain one or more pigments. These pigments are commonly susceptible to degradation upon exposure to solar UV and/or IR radiation.

In another embodiment, the substrate is a photovoltaic device. A photovoltaic device is a device that converts light energy into electrical energy. In preferred embodiments the light source for the photovoltaic device is the sun. The photovoltaic device may be made of various semi-conductor materials including silicon, cadmium sulfide, cadmium telluride, and gallium arsenide, and in single crystalline, multi-crystalline, or amorphous forms. Also, the photovoltaic device may be an organic or polymer-based device. The photovoltaic device may comprise polymer blends or comprise mixtures of conjugated polymers with nano-particles or nano-crystals of inorganic semiconductors.

When a photovoltaic device is used as a substrate for the coating composition of present invention, it is important that the coating components allow the sufficient transmission of visible light in the frequencies required to drive the photovoltaic device. To this end, the UV protective agent, IR reflective agent and other optional coating components are selected in combination to have a UV transmission window and to allow transmission of visible light. In preferred embodiments, the transmission window extends from the near UV through the visible spectrum (see FIG. 1A).

### Coating Polymer

The coatings of the present invention are urethane/acrylics. The urethane/acrylic coating is coated onto the substrate and cured using an ultraviolet radiation (UV) curing system. This has the advantage that the use of volatile organic solvents may be minimized or eliminated. Thus, the coating and process of the invention have the advantages of being environmentally friendly and of reducing or eliminating the cost of solvent recovery. One or more of the reactive monomers preferably provide the solvent-like properties and an appropriate viscosity for spray application of the coating.

In particularly preferred UV cured urethane/acrylic coatings, the coatings are based upon the use of difunctional aliphatic urethane oligomers. The urethane diacrylate oligomer constitutes a backbone of the coating and has the following general structure:

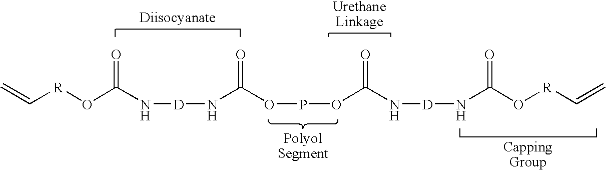

Preferred coatings may comprise a mixture of oligomers and monomers including alkoxylated acrylic monomers, acrylate monomers, and aliphatic urethane acrylates.

Other commercially available coatings may be appropriate for use in the present invention, such as Laromer UA 9048 (solvent-free urethane acrylate thinned with DPGDA).

To adjust the processing viscosity of the urethane diacrylate oligomer, it can be mixed with other acrylic resins as well as monomers such as dipropyleneglycol diacrylate (DPGDA), tripropylene glycol diacrylate (TPGDA) and the like, or mixtures thereof. These monomers may also be used as solvents for the other coating components.

The substrate is coated with a thin urethane/acrylic coating. Preferably the coating has a thickness of about 0.5 to about 3.0 thousandths of an inch. In many embodiments, conventional spray guns may be used to apply the coating. Other preferred methods of applying the coating are roll coating, vacuum coating and curtain coating. When the composite building material is a deck product, it may be coated on the embossed surface and the adjacent sides. The embossed (top) surface may have a thicker coating layer, for example about 1.0 to about 3.0 thousandths of an inch, and preferably about 2.0 to about 2.5 thousandths of an inch, than the coating thickness on the sides, which may be about 1.0 thousandths of an inch thick.

The UV curing of the coating is initiated by a photoinitiator that absorbs distinct energies of UV light and generates free radicals, which in turn initiate polymerization. When using a UV curing system, the selection of pigments and other coating additives may be performed to ensure that the pigment and other additives do not strongly absorb UV radiation at the same energy as the photoinitiator, such that action of the photoinitiator is impaired. When using the UV-cured coating, free radicals must be generated by specific wavelengths of ultraviolet energy acting on a free radical initiator dispersed within the coating. Since the preferred coating composition may contain many interfering fillers, pigments and other additives, both the type of initiator as well as its response to UV light becomes an important part of the system. UV radiation of the proper frequency must reach the interface between the substrate and coating in order to obtain a complete curing of the coating and to promote adequate adhesion of the coating to the substrate.

### Photoinitiator

The UV curing reactions are induced by the absorption of high intensity UV light by the photoinitiator, and subsequent free radical polymerization and crosslinking of the resins. Photoinitiators are compounds that absorb radiation and are thereby raised to an excited state. From this radiation induced excited state, the photoinitiators photolyze or degrade directly or indirectly into free radicals. These free radicals become the initiating species that cause the rapid polymerization of the photocurable formulations.

The photoinitiator may be any appropriate material that generates free radicals upon exposure to UV light, and includes, for example, bisaryl phosphine oxides, benzylic ketones and derivatives thereof, benzophenones and derivatives thereof, and mixtures thereof. Other preferred properties of the photoinitiator are that it be liquid borne with no VOC generation and that it not detract from long term weathering of the product. Appropriate photoinitiators include Esacure photoinitiators (for example, Esacure KTO 46), available from Lamberti. Other, bisaryl phosphine oxide (BAPO) type photoinitiators which are activated by longer wavelength UV light in the near visible region above about 430 nm may be appropriate. Other BAPO type photoinitiators are commercially available and include Irgacure 819, Irgacure 1800, Irgacure 1850, and the like. Benzophenone derivative may contribute to yellowing of the coating, and thus for some embodiments should be included in relatively minor amounts or omitted from the coating composition.

Preferably the photoinitiator is present in the coating material at an amount of from about 0.5 to about 10% by weight. In certain embodiments, a synergist may be added to the coating that facilitates the free radical generation of the photoinitiator. Synergists may include tertiary amines, acylated tertiary amines and alkoxylated acrylate monomers.

In preferred embodiments, the photoinitiator is selected which has a peak response to UV light in the transmission window of the coating composition and the UV source emits strongly in the same region of the UV spectrum. Thus, in preferred embodiments, the source of the UV light emits strongly in the region of about 380 nm to about 450 nm. This is also the preferred region of the UV spectrum to which the photoinitiator is sensitive. The photoinitiator is distributed uniformly through the coating, therefore the UV light photons must get through the coating mixture to the photoinitiator molecules located at the adhesion interface between the substrate and coating. The photoinitiator should also have a high reactivity, and high thermal stability, as well as being non-yellowing, and non-odorous.

When incorporating photoinitiators into the coating composition, it is generally preferred to dissolve the photoinitiator(s) in a monomer and then add the solution to the resin to ensure complete dissolution. A solid dispersion of photoinitiator in the formulation instead of a fully solubilized material may reduce the effective deployment of the photoinitiator and can lead to poor cure performance. Liquid photoinitiators can be added to either the monomer or the formulated coating as they are easier to dissolve.

### IR-Reflective Agent

The infrared reflective agent may be any suitable material that is compatible with the coating composition, is infrared reflective, and which does not interfere with the ultraviolet curing of the coating on the substrate. These agents reflect rather than absorb infrared light. This results in a relative cooling effect when exposed to solar radiation in comparison to the uncoated substrate. The lower solar heating of the material has many potential benefits, such as less expansion and contraction, less product degradation and improved comfort levels for materials that may contact the skin (for example, decking materials underfoot).

The IR reflective agent is selected to permit sufficient transmission of the required frequencies of UV radiation for activation of the free radical initiator throughout the depth of the coating. Particularly preferred IR reflective agents for use in the present coatings have both a low solar gain (high IR reflectivity) and sufficiently transmit UV radiation in the near or mid UV spectrum. Thus, although many IR reflective agents may also absorb UV light, the IR reflective agent should allow sufficient transmission of UV light from the UV source to allow the curing of the coating. More specifically, the IR reflective agent should sufficiently transmit the frequency of UV light that is used to activate the photoinitiator.

In certain preferred embodiments of the invention, the infrared reflective agent is an infrared reflective pigment. The pigments IR reflective pigments for use in the coating have a low solar gain. This results in a relative cooling effect as compared to other pigments. The lower solar heating of the material has many potential benefits, such as less expansion and contraction, less product degradation and improved comfort levels for materials that may contact the skin (for example, decking materials underfoot). The pigment(s) may be present in the coating in an amount of about 10% to about 20% by weight. Suitable pigments typically are fine ground mixed metal oxides and are commercially available, for example Ferro Corporation's Cool Colors and Eclipse pigments, and particularly colors 10364 (brown), V-9416 (yellow), V-13810 (red), and the like.

When the substrate is a photovoltaic device, the IR reflective agent is selected to be transparent to the frequencies of light to that drive the device. Typically the photovoltaic devices utilize light in the visible region of the spectrum. Thus, in preferred aspects of this embodiment, the IR reflective agent does not absorb or reflect light in the visible portion of the spectrum.

In one embodiment, the IR reflective agent comprises nanoparticles of titanium dioxide (TiO₂). This TiO₂ is advantageous as it has an infinite lifetime and is transparent in the visible range. Also, this product is also beneficial as it absorbs UV energy. The nanoparticle TiO₂ is available from Kimera (Finland).

The IR reflective agent may be dispersed in the coating composition using high energy liquid dispersators such as Cowles or Hockmeyer mixers. In preferred embodiments, the IR reflective agent is dispersed in a reactive urethane/acrylic precursor (oligomer or monomer) and is supplied in liquid form, preferably as a concentrate for later addition to the coating composition. This limits VOC's, which is environmentally important. It is often useful to use small additions of dispersing aid and suspension aids in preparing the dispersion of the pigments in the oligomer or coating composition.

### UV Protective Agent

Ultraviolet protective agents operate by absorbing incident ultraviolet light and are able to convert this into heat energy which can be dissipated through the polymer matrix in a non-damaging way. The UV protective agent is selected to be compatible with the coating composition and with the UV curing of the coating on the substrate. The UV protective agent is selected to allow sufficient transmission of the required frequencies of UV radiation for activation of the free radical initiator throughout the depth of the coating. Thus, particularly preferred UV protective agents for use in the present coatings absorb high frequency ultraviolet radiation and are sufficiently transparent to UV radiation in the near or mid-UV spectrum. More specifically, the UV protective agent should allow sufficient transmission of the frequency of UV light that is used to activate the photoinitiator. A preferred UV protective agent is nanoparticle TiO₂, for example available from Kimera (Finland). Other UV protective agents may include, but are not limited to, benzotriazoles (BZT), and hydroxyphenyl-s-triazines (HPT).

### UV Source

The UV lamp(s) consists of a quartz tube typically containing a small quantity of mercury. The preferred bulbs used in this invention are powered by microwave. The microwave energy vaporizes the mercury and when the bulb reaches operating temperature the vapor becomes plasma and emits characteristic wavelengths of UV light as well as some visible light. These lamps generate a tremendous number of photons which are needed for penetration of the UV light to the bonding interface.

The emission spectra two type UV bulbs are provided in FIGS. 4A and 4B. The H bulb (4A) uses conventional undoped mercury and although there is a “spike” of energy between 400 and 450 nm, most of the power is of lower (shortwave) which is heavily absorbed by the coating components and cannot be used by itself for curing. This bulb may be used for surface cure when used at a lower power level (fewer bulbs). Using this bulb provides excellent development of surface cure through use of the intense 400-450 nm “spike.” The use of doping in the mercury bulb allows the plasma to emit concentrated wavelengths in the desired transmission region. The “V” bulb (4B) is doped with gallium and shows a strong emission in the region of 400-450 nm. Both of the bulbs used have a high radiated power, which is needed. Suitable UV bulbs are commercially available, for example from Fusion UV Systems, including bulb13V-I600 and bulb13H-I600.

The number of bulbs and type of bulbs are manipulated for the rate of coating as well as limiting heat generation. Also significant is the effective irradiance or UV radiation reaching the coated product. Rate, distance and reflectors alter the irradiance and are manipulated for peak performance.

Since plasma often reaches 20,000 degrees F., the quartz tube of the UV bulbs heats and radiates infra red energy. It is important that the heat not reach the substrate and cause surface decomposition as most plastics will degrade quickly under high energy IR (heat) buildup. Thus, it may be important to limit the infra red emission through the use of heat absorbing reflectors and air cooled bulbs. Without the use of these elements, the generated heat may burn the substrate. The use of a chilled grid between the coated substrate and the lamp may also be needed at lower coating rates. The use of infrared reflective pigments that reflect substantial amounts of infra red energy may assists the coated substrate to withstand heat generated by the UV lamp.

In preferred embodiments, the UV-curable urethane/acrylic coating is applied to provide a coating thickness ranging from about 0.0005 to 0.003 inches. This range of film thickness generally provides optimum performance and provides the opportunity to use very intense ultraviolet light to penetrate the coating and provide enough energy at the substrate to cure the coating at the interface between the coating and substrate. This also promotes adhesion of the coating to the substrate. Multiple coats having this thickness may be applied, with curing between each coat. For certain embodiments, it has been found that adhesion is accelerated by preheating the substrate to between 160 and 190 degrees F. prior to the application of the coating.

The use of a UV coating system has the further advantage of reducing manufacturing space and increasing productivity. Typical cure times may be less than a second, allowing for higher line speeds. Thus, the use of a UV curing system is well suited for use in a process in which the substrate is coated with the urethane/acrylic coating as part of the same process for making the substrate. For example, the substrate may be coated immediately following embossing, followed by a radiation curing step. As the use of solvents may be minimized in this embodiment, the inclusion of one or more chemical agents in the substrate, coating or both that facilitate cross-linking of the substrate with the coating is particularly preferred. In certain embodiments, the surface of the substrate may be treated in a manner to facilitate physical keying of the coating to the substrate the surface prior, or concurrently with, the coating and radiation curing. For example, the surface of the substrate may be pre-heated, or pre-treated with a solvent.

Particulate alumina deglossing agents may be added to control surface gloss while enhancing scratch and mar resistance. The alumina may be added in an amount of about 1% to about 4% by weight. Specifically, alumina nanoparticle additives are commercially available from Byk Chemie as the Nanobyk additives, including Nanobyk-3602, Nanobyk-3610 and Nanobyk 3650.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

### EXAMPLES

### Example 1

A deck board according to the present invention was prepared having the composition set forth in Table 1.

TABLE 1
Substrate Composition

| Material | PPH |
|---|---|
| PVC Resin | 100 |
| (FPC 616) | |
| Stabilizer | 0.8 |
| (TM-181) | |
| Lubricant | 0.8 |
| (Paraffin 165) | |
| Lubricant | 0.15 |
| (PE AC 629A) | |
| Lubricant | 0.6 |
| (calcium strearate) | |
| Reinforcing Filler | 18 |
| (calcium carbonate, 0.7 | |
| micron treated UFT) | |
| Processing Aid | 6.0 |
| (K-400) | |
| Processing Aid | 1.5 |
| (K-175) | |
| Titanium Dioxide | 0.5 |
| Blowing Agent | 0.8 |
| (Forte-Cell 247 Azo) | |

The ingredients from Table 1 are loaded into on-line feeders which are calibrated for each individual material dose rate. The raw material feeder systems used to make may be volumetric or gravimetric, or combinations of each. These feeder systems deliver the pre-calibrated volume or weight of each material to a central neck piece which is attached to the feed port of the extruder. Materials are delivered in a “Starve feed” mode which allows the extruder screws to be covered approximately 90% of total depth.

The raw materials described in the preceding paragraph are mixed in an extruder. The extruder is a counter-rotating, profile twin screws (either conical or parallel screws). The extruder melt-mixes, or flux's, the compound ingredients using shear, heat, and pressure to form a homogeneous molten mass containing an evenly distributed mixture of the raw materials. Melt temperature is the extruder is of 350-360 degree with a pressure of about 1200-3000 psi. The extrusion is performed at a rate about 300 pounds per hour (conical) or about 1200 pounds per hour (dual-strand). The extrusion process prepares the compound to be shaped into the deck form that becomes our final product.

The next part of or process is the exit of the molten or fluxed compound from the extruder into the die. The process uses a Celuka die design, which enables the foamed vinyl compound to yield a deck board that is dense at the surface with an integral skin on all sides. The product density gradient goes from a high density surface to a lower density (foamed) core. The Celuka die is attached to the end of the extruder and receives the molten or fluxed compound. The die, is a high inventory, advancing compression streamlined Celuka die, which is configured using a series of sequential plates and mandrels. The die forms the initial shape of the deck board.

The next process phase is the calibration phase. The calibration step involves receiving the still hot formed deck shape from the die and finishing the formation of the deck board. A small lead-in plate at 55° F. is employed to presize the extruded deck board. The extruded board then passes through a train of 6-1′ foot long dry-sleeve calibrators that contain water and vacuum slots. The calibrator train helps form the tough integral skin and through the use of water and vacuum form and stabilize the final detailed shape of the deck board.

After calibration the deck board enters a series of cooling tanks equipped with chilled water spray systems. This chilled water spray is applied to the deck board on all sides and continues the cooling process of the deck board. This section of the process can be long, sometimes exceeding 50 to 60 feet. The spray tanks are typically operated under vacuum to help maintain the calibration shaped deck board. The spray tanks are typically equipped with rollers or templates that continue to hold the deck shape as cooling progresses.

Next, the deck board exits the vacuum cooling tanks and is put through an embosser that embosses the grain pattern into the surface of the board. To accomplish the, embossing the deck board is surface heated using an IR light sources to prepare the deck board surface to receive the embossing pattern. The surface temp is about 220° F. on the embossing surface, with a compensating heat on the opposite surface to avoid warping. The hydraulic embosser rolls are heated, with the top roll at about 350-400° F. and the bottom roll at about 250-300° F., and applies a pressure of 800-1200 pli.

The deck board is allowed to cool slightly before being cut to length. Usually these lengths are 12′, 16′, and 20′ long. The saw is part of the puller system which carefully controls the speed of the board as it enters the calibration stage until it is cut to length.

The UV-curable urethane/acrylic coating used to coat the board has the composition set forth below:

| Material | Weight % |
|---|---|
| urethane acrylic: | 90.7% |
| 10% Alkoxylated Acrylic Monomer | |
| 10% Acrylate Monomer | |
| 5% Highly Functional Monomer | |
| 38.5% Aliphatic Urethane Acrylate | |
| Esacure KTO46 photoinitiator | 3% |
| 30% Ferro Geode Pigments in PMDA | 10-20% (based |
| | on solids) |
| Nano Byk 3601 40 nm aluminum oxide in | 3.6% |
| TPGDA | |
| Acematt TS100 | 1.4% |

The urethane/acrylic monomer/oligomer composition is transferred to an appropriate vessel. The photo initiator is in liquid form and is mechanically stirred into the batch. Once the photoinitiator is added, the material must be kept away from any UV light sources and the material will have at least a two year shelf life when drummed and sealed.

The pigments (Ferro Geode) are dispersed in a reactive Sartomer oligomer (PDMA) and are supplied in liquid form. The Pigment concentrate dispersion is mixed in with the other components in stainless steel vessels using a propeller mixer at low speed so as to avoid air entrapment. Small additions of surfactant defoamers are used.

The Nano Byk 3601 40 nm aluminum oxide in TPGDA is added to the coating mixture. This ingredient is a liquid which is an oligomer reactant and is mixed using mild propeller action. The Silica is mixed into the coating mixture as above.

The deck board is transported through the process equipment by belt or roller conveyors. The deck board is cleaned at a rotary brush station where the brushes are nylon or abrasive impregnated nylon filaments. The coating is applied in a spray chamber where automatic paint guns apply the coating to the product surface at a thickness of 1 mil. The coating is delivered to the spray gun by a circulating system. Air for atomizing the coating is also supplied. To maximize coating efficiency, overspray is captured in drip pans and filter banks.

The coating is cured in a UV oven which is configured with Fusion “V” and “H” bulbs. Heat from the enclosed oven is removed by an exhaust system. To apply coating at a thickness greater than 1 mil the product is processed through the process line a second time (decking) or an additional spray chamber and UV oven added to the described configuration.

1. A UV-curable coating composition comprising:
(a) a urethane-acrylic polymer precursor;
(b) an infrared reflective agent;
(c) an ultraviolet protective agent; and
(d) a photoinitiator;
wherein the infrared reflective agent and the ultraviolet protective agent are selected to provide an ultraviolet transmission window which sufficiently transmits ultraviolet radiation from an ultraviolet source with a frequency that corresponds to the photoinitiator;
and wherein the photoinitiator is activated by ultraviolet light from the ultraviolet light source at a frequency within the ultraviolet transmission window.

2. The UV-curable coating composition of claim 1, wherein the urethane-acrylic polymer precursor comprises a urethane diacrylate oligomer.

3. The UV-curable coating composition of claim 2, wherein the urethane-acrylic polymer precursor further comprises monomers selected from alkoxylated acrylic monomers, acrylate monomers, and aliphatic urethane acrylates

4. The UV-curable coating composition of claim 1, wherein the infrared reflective agent is an infra-red reflective pigment.

5. The UV-curable coating composition of claim 4, wherein the infrared reflective pigment comprises a metal oxide pigment.

6. The UV-curable coating composition of claim 1, wherein the infrared reflective agent comprises nanoparticle titanium dioxide.

7. The UV-curable coating composition of claim 1, wherein the photoinitiator comprises a bisaryl phosphine oxide.

8. The UV-curable coating composition of claim 1, wherein the ultraviolet protective agent is a nanoparticle titanium dioxide.

9. The UV-curable coating composition of claim 1, wherein the ultraviolet protective agent is selected from benzotriazoles and hydroxyphenyl-s-triazines.

10. A composition comprising a substrate and a UV-cured coating applied on at least one surface of the substrate, wherein
the coating has a pre-cure composition comprising
(a) a urethane-acrylic polymer precursor;
(b) an infrared reflective agent;
(c) an ultraviolet protective agent; and
(d) a photoinitiator;
wherein the infrared reflective agent and the ultraviolet protective agent are selected to provide an ultraviolet transmission window which sufficiently transmits ultraviolet radiation from an ultraviolet source with a frequency that corresponds to the photoinitiator;
and wherein the photoinitiator is activated be ultraviolet light from the ultraviolet light source at a frequency within the ultraviolet transmission window.

11. The composition of claim 10, wherein the substrate is a composite building material.

12. The composition of claim 10, wherein the substrate is a photovoltaic device.

13. The UV-curable coating composition of claim 10, wherein the urethane-acrylic polymer precursor comprises a urethane diacrylate oligomer.

14. The UV-curable coating composition of claim 13, wherein the urethane-acrylic polymer precursor further comprises monomers selected from alkoxylated acrylic monomers, acrylate monomers, and aliphatic urethane acrylates

15. The UV-curable coating composition of claim 10, wherein the infrared reflective agent is an infra-red reflective pigment.

16. The UV-curable coating composition of claim 15, wherein the infrared reflective pigment comprises a metal oxide pigment.

17. The UV-curable coating composition of claim 10, wherein the infrared reflective agent comprises nanoparticle titanium dioxide.

18. The UV-curable coating composition of claim 10, wherein the photoinitiator comprises a bisaryl phosphine oxide.

19. The UV-curable coating composition of claim 10, wherein the ultraviolet protective agent is a nanoparticle titanium dioxide.

20. The UV-curable coating composition of claim 10, wherein the ultraviolet protective agent is selected from benzotriazoles and hydroxyphenyl-s-triazines.
